(19) United States
(12) Patent Application Publication
(10) Pub. No.: US 2008/0308417 A1
(43) Pub. Date: Dec. 18, 2008

(54) Sputtering Apparatus

(76) Inventors: Toyoaki Hirata, Osaka (JP); Masami Nakasone, Osaka (JP)

Correspondence Address: MCDERMOTT WILL & EMERY LLP, 600 13TH STREET, N.W., WASHINGTON, DC, 20005-3096, US

(21) Appl. No.: 11/886,436

(22) PCT Filed: Mar. 14, 2005
(86) PCT No.: PCT/JP2005/004474

§ 371 Date: Sep. 14, 2007

(51) Int. Cl. C23C 14/00

(52) U.S. Cl. 204/298.14

(57) ABSTRACT

A sputtering apparatus includes target holders 4a and 4b for mounting targets thereon to constitute a cathode, a substrate holder 30 for holding a substrate 8, and magnets 51a and 51b for generating magnetic fields around the surface of the targets. A voltage is applied to backing plates 42 of the target holders 4a and 4b using a direct-current power supply 6 to generate plasma. An anode is made of an electrically-conductive material that is not molten by the retained, heated plasma with a high density. The anode 9 is connected to the ground electrical potential. At least a portion of the anode 9 is placed in or near the region where plasma is retained. During sputtering, electrons discharged from the target flow to the ground potential through the heated portion of the anode 9 being heated by the plasma, thereby keeping the direct-current power supply circuit closed. This can prevent electric-discharge abnormalities within the chamber with a simple configuration, without using an expensive pulsed power supply or a shielding plate.

### TECHNICAL FIELD

The present invention relates to a sputtering apparatus with which a target and a substrate are disposed within a vacuum chamber, and a voltage is applied to the target to generate plasma, thereby depositing a thin film on a surface of the substrate.

### BACKGROUND ART

Sputtering apparatuses include magnetron sputtering apparatuses such that a substrate and a target are positioned to face each other, and opposite-targets type sputtering apparatuses such that two targets are positioned to face each other and a substrate is positioned away from the targets.

These sputtering apparatuses are used for depositing, on a substrate, an insulation film such as a SiO₂ film, a Si₃N₄ film or a SiON film or an electrically-conductive film such as an ITO (Indium Tin Oxide) film.

In a sputtering apparatus, a target, a target holder for mounting the target thereon, a magnet positioned near the back surface of the target, and a substrate disposed spaced apart from the target are positioned in a chamber that is depressurized. Further, a voltage from a direct-current power supply is applied to the target holder to generate plasma around a surface of the target, and the generated plasma is retained by a magnetic field generated by the magnet, thereby depositing a thin film on the substrate.

The aforementioned sputtering apparatus is a direct-current reactive sputtering apparatus, and usually, a direct-current power supply circuit is constituted by a shield cover provided around the target or a surface of inner walls of the chamber to be a deposition chamber used as a ground electrode, and the target holder which is electrically insulated from the surface of the inner walls of the chamber used as a cathode.

Further, in the sputtering apparatus, electric power from a direct-current power supply is supplied to the target holder and the ground electrode constituted by the surface of the inner walls of the chamber or the shield cover, while an inert gas such as Ar gas is supplied to the target, thereby ionizing the inert gas to generate plasma around an upper surface of the target to which the voltage has been applied. The target is sputtered by the generated plasma to deposit a thin film having a composition corresponding to the composition of the target, on the substrate surface. At this time, the plasma is retained near the target by the magnet positioned near the back surface of the target and the retained plasma is used for sputtering the target.

Particularly when an insulation oxide film is formed on a substrate, a reactive gas such as oxygen gas is introduced toward the substrate to oxidize sputtered target atoms and then the oxidized atoms form an insulation film on the substrate.

However, in a direct-current reactive sputtering apparatus, during sputtering for depositing a thin film, an insulation thin film is also gradually formed on the chamber inner wall surface and the shield cover from target atoms and reactive gas, and the electric-discharge voltage within the chamber rises. Especially, as the insulation of the thin film being formed on the chamber inner wall surface increases, conclusively, the surface of the inner walls of the chamber constituting the ground electrode becomes completely insulated. If the ground electrode is insulated in this way, electric-discharge abnormalities such as arc discharge can be induced during sputtering.

As a method for preventing such electric-discharge abnormalities from occurring, such a method as described in Patent Document 1, for example, that uses a direct-current pulsed power supply has been suggested. The method using a pulsed power supply is such that, by the direct current, a negative potential is applied to the target-side electrode, and a voltage is intermittently applied to the target-side electrode so that the peak positive electric potential at the target-side electrode is greater than the electric potential at the ground electrode on the chamber side in the positive direction. Then, the peak voltage is applied to the target-side electrode so as to periodically neutralize the electric charge accumulated in the insulation film that has been locally formed on the target surface during sputtering, thereby preventing the electric-discharge abnormalities from occurring.

Moreover, it is also conceivable to suppress the formation of a thin film on the anode and prevent the electric-discharge abnormalities from occurring by, instead of using the surface of the inner walls of the chamber or the shield cover as the ground electrode, positioning a bar-shaped anode at a position spaced apart from the target within the chamber, and providing a shield plate on the portion of the anode near plasma for shielding the anode from plasma.

Patent Document 1: Japanese Patent Publication No. 7-243039 (Unexamined)

### DISCLOSURE OF INVENTION

### Problem to be Solved by the Invention

However, in the case of using a pulsed power supply for preventing electric-discharge abnormalities, such a pulsed power supply is more expensive than a common direct-current power supply. Further, it is necessary to set the frequency and the pulse width depending on the type of the to-be-used target, thus increasing the difficulty of setting of conditions and involving complicated operations. Further, the application of positive potential pulses to the target produces losses of the power for sputtering, which reduces the deposition rate to one-third that of the case of not applying a positive electric-potential to the target, thus significantly reducing the sputtering efficiency and providing disadvantages to mass production.

Further, even in the case of using a pulsed power supply, it will conclusively become impossible to neutralize accumulated electric charge, thus resulting in the occurrence of electric-discharge abnormalities within the chamber.

Moreover, in the case of providing a shielding plate, there is a need for a space for placing the anode and the shielding plate outside of the target, thus requiring a larger chamber. Further, even when such a shielding plate is provided, sputtered target atoms are introduced to the portion of the shielding plate which is faced to the anode. Consequently, as sputtering is repeatedly performed, an insulation film is gradually formed on the anode surface, thus resulting in the occurrence of electric-discharge abnormalities.

It is an object of the present invention to provide a sputtering apparatus capable of certainly preventing the occurrence of electric-discharge abnormalities within the chamber with a simple configuration without using an expensive pulsed power supply and a shielding plate.

### Means to Solve the Problems

The present invention can prevent electric-discharge abnormalities in a sputtering apparatus. Particularly, the present invention can certainly prevent electric-discharge abnormalities in a direct-current reactive sputtering apparatus.

A sputtering apparatus according to the present invention includes a target holder that constitutes a cathode with a target being mounted thereon, a substrate holder that holds a substrate away from the target, a chamber in which the holders are disposed, and a magnet that generates a magnetic field around a surface of the target. In addition, the sputtering apparatus according to the present invention applies a voltage from a direct-current power supply to the target holder and supplies inert gas near the target surface to generate plasma so as to be retained by the magnetic field generated by the magnet. The plasma retained with a high density by a magnetic field sputters the target, and the sputtered target atoms are deposited on the substrate surface to form a thin film on the substrate.

According to the present invention, in the aforementioned sputtering apparatus, an anode made of an electrically-conductive material that is not molten by heating from the retained plasma is connected to a ground potential, and at least a portion of the anode is disposed in or in vicinity of a region where the plasma is retained with a high density.

As the material of the anode, it is possible to employ an electrically-conductive material having a melting point of 1000° C. or higher, such as molybdenum (with a melting point of 2620° C.), tungsten (with a melting point of 3410° C.), tantalum (with a melting point of 2996° C.).

The plasma-retaining region, in which the anode is placed, is heated to a significantly high temperature by the high-density plasma. The anode placed in this region is heated to a high temperature. Even when reactive gas is supplied to the chamber, the portion of the anode being heated to a high temperature cannot react with the reactive gas, which prevents the formation of an insulation film on the heated portion.

Accordingly, even when an insulation film such as an oxide film is formed on the exposed surfaces of the anode other than the heated portion, no insulation film is formed on the heated portion, which enables electrons discharged from the target to be grounded through the heated portion of the anode anytime. As a result, even when an insulation film is formed on the inner wall surface of the chamber, the anode according to the present invention can keep the direct-current power supply circuit closed during sputtering.

According to the present invention, it is preferable that the anode is constituted from an elongate member with a narrow width. For example, the anode may be formed from a long plate-shaped member made of an electrically-conductive material having a high melting point with a narrow width and a small thickness (with a width of 1 cm and a thickness of 1 mm, for example). Preferably, such a long plate-shaped member with a narrow width and a small thickness has a width of 1 cm or less and a thickness of 1 mm or less. In this case, the tip end portion of the long plate-shaped member is positioned in or in vicinity of the plasma-retaining region near the target, while the other end portion is connected to, for example, surface of inner walls of the chamber, and therefore is connected to the ground potential through the surface of inner walls of the chamber.

Also, the anode may be formed from a wire-shaped member, instead of a narrow-width plate member. In the case of employing a wire-shaped member, it is preferable that the wire diameter is 1 mm or less. If the anode to be heated by plasma has an excessively large cross-sectional area, the heat generated therein by the plasma will be easily released to the portion of the anode which is not heated. If heat is released as described above, this will decrease the temperature of the portion being heated by the plasma and the portion will become prone to oxidation. Therefore, by reducing the thickness or width of the anode or the wire diameter and, therefore, the cross-sectional area of the anode, it is possible to maintain the state where the anode is heated.

Further, it is preferable that the anode includes a position adjustment mechanism for adjusting a position of the anode with respect to the region where plasma is retained.

In this case, the anode may include a first member having a long plate shape with a narrow width and a second member having a plate shape, wherein one end of the first member is placed in the plasma-retaining region, the first member is mounted on the second member such that the position thereof is adjustable and a portion of the second member is connected to the ground potential.

When the anode is constituted by the first member and the second member, the first member may be formed form an elongate plate-shaped member made of an electrically-conductive material having a high melting point with a narrow width and a small thickness (with a width of 1 cm or less, a thickness of 1 mm or less and a length of 10 cm or less, for example). The second member may be formed from a plate-shaped member made of the same material as that of the first member or an electrically-conductive material with a lower melting point than that of the first member. The second member may be formed from an elongate plate-shaped member with the same width as that of the first member. Also, the second member may be formed from a member having a greater surface area than that of the first member.

Further, the first member has a bolt inserting hole for inserting a bolt therethrough at a position spaced apart from the portion placed in plasma, namely at the joining position with the second member. Further, the second member preferably has a long hole for inserting the bolt therethrough at the joining position with the first member. The bolt inserting hole in the first member, the long hole in the second member and the bolt or a nut constitute the position adjustment mechanism.

In the case of employing the first member and the second member, the second member is connected to the chamber inner wall surface or the target shield cover insulated from the target holder. The shield cover is made of an electrically-conductive material. The chamber wall or the shield cover is connected to the ground potential.

At a state where the position of the bolt inserting hole of the first member is aligned with the long hole of the second member, the bolt is inserted through the both holes and then the nut is mounted to the bolt to temporally secure them. Then, the position of the first member is adjusted along the long hole such that the tip end portion of the first member is placed at a predetermined position near the target. Thereafter, the bolt and the nut are firmly tightened to secure the first member to the second member.

With the anode including the first member and the second member, the tip end portion of the first member is heated by plasma and electrons discharged from the target flow to the ground potential through the tip end portion of the first member and the second member, during sputtering.

Also, with the anode includes the first member and the second member, the first member may include a fixed portion having the bolt inserting hole for joining the first member to the second member by inserting a bolt therethrough, and a narrow-width portion having a smaller width than that of the fixed portion. The fixed portion and the narrow-width portion may be continuously formed, and the narrow-width portion may have a tapered tip end portion.

By forming the tip end portion of the first member to be a tapered shape, it is possible to facilitate the concentration of electrons at the tapered portion.

The first member may also include a fixed portion having the bolt inserting hole for joining the first member to the second member by inserting a bolt therethrough, and a narrow-width portion having a smaller width than that of the fixed portion, and the fixed portion and the narrow-width portion may be continuously formed, and the narrow-width portion may be provided at its tip end portion with a mesh-shaped member made of an electrically-conductive material. In this case, it is preferable that the meshed-shaped member is formed such that some of the wires constituting the mesh are protruded at their tip end portions towards the generated plasma.

By providing a mesh-shaped member at the tip end portion of the first member, it is possible to facilitate the concentration of electrons at the tip end portions of the wires of the mesh-shaped member.

Also, the position adjustment mechanism for adjusting the position of the anode with respect to the region where plasma is retained may be configured to enable adjusting the anode position from outside of the sputtering apparatus. Preferably, the position adjustment mechanism includes an operating portion for adjusting the anode position, outside of the sputtering apparatus, and further includes an observation window for visually observing the inside of the apparatus, in the casing of the apparatus.

The anode according of the sputtering apparatus of the present invention may be applied to an opposite-target type sputtering apparatus and a magnetron sputtering apparatus.

### EFFECTS OF THE INVENTION

With the sputtering apparatus according to the present invention, the anode is provided such that at least a portion thereof is positioned in or near the plasma-retaining region, near the target. Therefore, during sputtering, gamma electrons or the like discharged from the target flow to the ground potential through the portion of the anode being heated by plasma. As a result, even when an insulation film is formed on the chamber inner wall surface, the anode of the present invention can keep the direct-current power supply circuit at a closed state, which prevents rises of the electric-discharge voltage within the chamber, thereby certainly preventing electric-discharge abnormalities from occurring.

### BEST MODE FOR CARRYING OUT THE INVENTION

Embodiments of the sputtering apparatus according to the present invention will be described on the basis of the drawings.

### First Embodiment

A sputtering apparatus according to a first embodiment is an opposite-target type sputtering apparatus as illustrated in FIG. 1.

The sputtering apparatus 1 according to the present embodiment includes a pair of plate-shaped targets 21a and 21b which are made of, for example, silicon and are placed oppositely to each other with an interval interposed therebetween within a vacuum chamber 3. The pair of targets 21a and 21b are supported on a pair of supporting cylindrical members 31 with a rectangular cross-sectional area which are secured within the chamber 3, through target holders 4a and 4b, although illustration thereof is omitted in FIG. 1.

The two supporting cylindrical members 31 each include, on the opening portion thereof at the target-mounting side, a first flange portion 31a formed to extend toward the center of the opening portion.

Target holders 4a and 4b are each secured to the first flange portion 31a of the supporting cylindrical member 31 through a ring-shaped insulation member 44. The target holders 4a and 4b are each constituted by a magnet housing portion 41 having a cubic cylindrical shape with a bottom and a rectangular backing plate 42 which covers the opening portion of the magnet housing portion 41. The insulation members 44 are formed to be a plate-shaped ring made of a ceramic or a synthetic resin such as Teflon (trademark).

The magnet housing portions 41 each include, on the opening portion thereof, a second flange portion 41a formed to extend radially outwardly. The magnet housing portions 41 house a cylindrical magnet 51a and 51b. The magnets 51a and 51b are each secured to the magnet housing portion 41, near the opening portion thereof, through adhesive materials or bolts. The backing plates 42 forming a cover are each mounted to the second flange portion 41a of the magnet housing portion 41 housing the magnet 51a and 51b. Further, the outer peripheral edge of each backing plate 42 and the second flange portion 41a of each magnet housing portion 41 are secured to the first flange portion 31a of the supporting cylindrical member 31 through bolts (not shown) Further, as previously described, the insulation member 44 for insulation from the ground potential is interposed between the second flange portion 41a of the magnet housing member 41 and the first flange portion 31a of the supporting cylindrical member 31.

The inner surfaces of the backing plates 42 at the side of the magnet housing portions 41 are connected to the negative electrode of a direct-current power supply 6 while the targets 21a and 21b are secured to the outer surfaces thereof. The pair of targets 21a and 21b are supported on the target holders 4a and 4b such that they are parallel to each other. In the present embodiment, the target holders 4a and 4b and the targets 21a and 21b form a cathode while the inner wall surface of the chamber 3 is maintained at the ground potential (0V).

Further, a shield cover 71 for shielding the target 21a, and 21b is secured to each of the supporting cylindrical members 31, on the opening portion thereof near the first flange portion 31a.

Further, the magnets 51a and 51b housed within the magnet housing portions 41 are positioned near the back surfaces of the targets 21a and 21b and, consequently, the pair of magnets 51a and 51b create a magnetic field space between the targets 21a and 21b.

As illustrated in FIG. 1, the pair of magnets 51a and 51b are placed such that their portions opposing to each other form opposed poles to create lines of magnetic forces running from one of the target holders 4a to the other target holder 4b. Namely, the magnet 51a on one of the target holders 4a (the right magnet in FIG. 1) is placed such that its N pole is faced toward the target while the magnet 51b on the other target holder 4b (the left magnet in FIG. 1) is placed such that its S pole is faced towards the target. As the material of the magnets 51a and 51b, it is possible to employ various types of known magnets such as ferrite magnets.

The aforementioned shield covers 71 each have a rectangular opening portion 71a covering the outer peripheral edge of the surface of the target 21a, 21b. The shield covers 71 are each formed from, for example, a plate-shaped member made of a stainless steel and the opening portions 71a are shaped such that the depth wise length in FIG. 1 is greater than the vertical length in FIG. 1. The opening portions 71a may also have a round shape or an elliptical shape. When the supporting cylindrical members and the target holders are formed to have around cylindrical shape, it is preferable that the shield covers are also formed to have around cylindrical shape. In this case, it is preferable that the opening portions of the shield covers have a round shape.

A substrate 8 is placed at a position facing to the space region (the magnetic-field space) between the targets 21a and 21b, at a side portion of the pair of the target holders 4a and 4b (above the targets illustrated in FIG. 1). The substrate 8 is secured to a substrate holder 30.

Between the substrate 8 and the target holders 4a and 4b, a plate-shaped partition wall 32 is placed. An opening 32a is formed in the partition wall 32 such that it faces toward the space region between the targets 21a and 21b. In the present embodiment, the opening 32a is formed to have a rectangular shape such that the depth wise length in FIG. 1 is greater than the lateral length in FIG. 1. Also, the opening portion in the partition wall 32 may have a round shape or an elliptical shape.

Reactive-gas supplying pipes 33 for supplying reactive gas such as oxygen gas or nitrogen gas are opened, near the opening 32a of the partition wall 32, at the side of the substrate 8. The reactive gas is supplied from a reactive-gas supplying portion, not shown, to the inside of the chamber through the reactive-gas supplying pipes 33 and is discharged from the opening portions of the reactive-gas supplying pipes 33 toward the substrate 8.

Further, a vacuum pump 34 is connected to the chamber 3 via an exhaust pipe 34a so that the inside of the chamber 3 is depressurized by the vacuum pump 34.

Inert-gas supplying pipes 35 for supplying inert gas such as argon gas are opened, at the side portion of the space between the targets 21a and 21b at the opposite side from the openings of the reactive-gas supplying pipes 33. The inert gas is supplied from an inert-gas supplying portion, not shown, to the inside of the chamber through the inert-gas supplying pipes 35 and is discharged from the opening portions of the inert-gas supplying pipes 35 toward the magnetic-field space.

In the present embodiment, an anode 9 made of an electrically-conductive material which is not molten by heated plasma retained by magnetic fields is placed such that a portion thereof is positioned in or near the targets 21a and 21b and near the region where plasma is retained with a high density and another portion thereof is connected to the ground potential. The placing of the anode 9 in or near the region where plasma is retained with a high density means placing the anode in or near a light-emitting plasma region, since such a light-emitting plasma region generated by electric discharge can be visually recognized.

The configuration of the anode 9 will be concretely described now. As illustrated in FIGS. 1 to 4, the anode 9 includes a first member 91 having an elongate plate shape with a narrow width, one end of which is positioned at the boundary of the plasma-retaining region, and a second member 92 having a plate shape, to which the other end of the first member 91 is joined with a joining position adjustable, and a part of which is connected to the ground potential.

The first member 91 is made of a metal material having a high melting point, such as tungsten, tantalum, molybdenum or niobium. As illustrated in FIGS. 2 and 3, the first member 91 is formed from an elongate plate member with a narrow width and a small thickness (with a width of 10 cm or less, a thickness of 1 mm or less and a length of 10 cm or less). The first member 91 has a bolt inserting hole 91a for inserting a bolt 93 therethrough, at a position spaced apart from the tip end portion to be placed in or near plasma.

The second member 92 may be made of the same metal material as that of the first member 91. Also, the second member 92 may be made of the same stainless steel material as that of the shield covers 71 since it is positioned at a position spaced apart from plasma. The second member 92 is an elongate plate-shaped member having the same width as that of the first member 91 and has an L-shaped cross sectional area with a bent portion. The second member 92 is secured at an one-side piece of the L shape thereof to the outer surface of the shield cover 71 such that the bent portion thereof is spaced apart from the surface of the shield cover 71, and the first member 91 is abutted and secured to the upper surface of the other piece.

Through the surface of the second member 92 which abuts against the first member 91, there is formed a long hole 92a for inserting the aforementioned bolt 93 therethrough and for enabling the adjustment of the position of the first member 91 with respect to the second member 92.

The portion of the second member 92 which is mounted on the shield cover 71 is connected to the ground potential, as illustrated in FIG. 1. The second member 92 may be connected to the ground potential via the inner wall surface of the chamber 3, although it is not illustrated.

Further, the first member 91 is secured to the second member 92 which is secured to the shield cover 71. As illustrated in FIG. 2, at the state where the position of the bolt inserting hole 91a of the first member 91 is aligned with the long hole 92a of the second member 92, the bolt 93 is inserted through the both holes and then a nut 94 is mounted to the bolt 93 to temporally secure them. Then, the first member 91 is moved along the long hole 92a in the longitudinal direction and positioned at such a position that the tip end portion of the first member 91 will be heated to a proper temperature which can prevent the formation of an oxide film thereon when being heated by plasma. After the adjustment of the position, the bolt 93 and the nut 94 are firmly tightened to secure the first member 91 to the second member 92.

In the present embodiment, the bolt inserting hole 91a of the first member 91, the long hole 92a of the second member 92, the bolt 93 and the nut 94 constitute the position adjustment mechanism.

The tip end portion of the first member 91 is positioned near the outer region of the region where plasma is retained with a high density, namely the boundary thereof, in the vicinity of the targets 21a and 21b. The plasma-retaining region is heated to a significantly high temperature through plasma and, when the tip end portion of the first member 91 is placed in this region, the tip end portion is heated to a high temperature by plasma. When the tip end portion of the first member 91 is heated to a high temperature, even though reactive gas is supplied to the inside of the chamber, this reactive gas causes no reactions at the tip end portion of the first member 91 and no insulation film is formed on the tip end portion.

With the present embodiment, during sputtering, the tip end portion of the first member 91 is heated by plasma and no insulation film is formed thereon, which allows electrons discharged from the target to be flowed to the ground potential through the tip end portion of the first member 91 and the second member 92.

Accordingly, no insulation film is formed on the heated portion of the first member 91, which enables electrons discharged from the target to be grounded through the heated portion of the anode anytime, even when an insulation film is formed on the exposed surfaces of the anode 9 other than the heated portion, such as the surface of the first member 91 which is not abutted against the second member 92 or the surface of the second member 92 which is exposed to the inside of the chamber. As a result, even when an insulation film is formed on the inner wall surface of the chamber, the anode 9 can keep the direct-current power supply circuit closed, which prevents rises of the electrical-discharge voltage within the chamber 3, thereby certainly preventing electrical-discharge abnormalities.

### Second Embodiment

In the aforementioned first embodiment, the anode 9 constituted by the first member 91 and the second member 92 is placed such that its tip end portion is placed over the side (the longer side) of the opening portion 71a of the shield cover 71 which is closer to the substrate 8. However, as illustrated in FIG. 5, the anode 9 may be placed such that its tip end portion is placed over a shorter side of the opening portion 71a of the shield cover 71.

In the case of placing the anode 9 in such a manner, it is preferable that the anode is provided near the side where the amount of discharged target atoms is smaller, rather than at a position where target atoms are supplied to the substrate 8, since the anode 9 will not obstruct the deposition of a film onto the substrate 8, thus increasing the efficiency of the film deposition onto the substrate.

### Third Embodiment

In the first embodiment, the first member 91 used in the anode 9 is a plate-shaped member having a single width. However, as in the third embodiment illustrated in FIG. 6, the first member 91 may be formed to have a fixed portion 91b with a bolt inserting hole 91a which is secured to the second member 92 and a narrow-width portion 91c having a width smaller than that of the fixed portion 91b, the fixed portion 91b and the narrow-width portion 91c being continuously formed, wherein the narrow-width portion 91c may have a tapered tip end portion.

In the present embodiment, the fixed portion 91b of the first member 91 has the same width as that of the second member 92 and the narrow-width portion 91c of the first member 91 has a smaller width than that of the fixed portion 91b.

With the present embodiment, the first member 91 has a tapered tip end portion, which facilitates the concentration of electrons discharged from the target at the tapered portion.

### Fourth Embodiment

As in the fourth embodiment illustrated in FIG. 7, instead of the first member 91 of the anode 9 according to the first embodiment, the first member 91 may be formed to have a fixed portion 91b with a bolt inserting hole 91a which is secured to the second member 92 and a narrow-width portion 91c having a width smaller than that of the fixed portion 91b, the fixed portion 91b and the narrow-width portion 91c being continuously formed, wherein the narrow-width portion 91c may be provided with a mesh-shaped member 91d, at its tip end portion. In this case, as illustrated in FIG. 7, it is preferable that the meshed-shaped member 91d is formed such that some of the wires are protruded at their tip end portions towards plasma. In the fourth embodiment, similarly, the fixed portion 91b of the first member 91 has the same width as that of the second member 92 and the narrow-width portion 91c of the first member 91 has a smaller width than that of the fixed portion 91b.

By providing a mesh-shaped member at the tip end portion of the first member, it is possible to facilitate the concentration of electrons at the tip end portions of the wires of the mesh-shaped member.

### Fifth Embodiment

The first to fourth embodiments have been described with respect to cases of providing the anode in an opposite-target type sputtering apparatus. However, as illustrated in FIG. 8, the anode according to the present invention can be applied to a magnetron sputtering apparatus which disposes a target and a substrate oppositely to each other.

A magnetron sputtering apparatus 10 illustrated in FIG. 8 includes a single plate-shaped target 22 and a substrate 8 placed opposite to the target 22, within a vacuum chamber 3. The substrate 8 is secured to a substrate holder 30. The target 22 is secured to a plate-shaped backing plate 43 and is provided within the chamber 3 such that it is insulated from the chamber 3. Further, the outer peripheral edge of the target 22 is shielded by a shield cover 72 secured to the inner wall of the chamber 3. The shield cover 72 is made of an electrically-conductive material such as a stainless steel.

Plural magnets 52 are placed near the back surface of the backing plate 43 such that their opposite poles are faced to each other. Accordingly, these magnets 52 create magnetic fields around the upper surface of the backing plate 43 to retain generated plasma above the target 22 with the magnetic fields. The backing plate 43 is secured to the chamber 3 with a ring-shaped insulation member 45 interposed therebetween.

Further, there are provided an inert-gas supplying portion 36 for supplying inert gas such as argon to the inside of the chamber 3, a reactive-gas supplying portion 37 for supplying reactive gas such as oxygen to the inside of the chamber 3 and a vacuum pump 34 for depressurizing the inside of the chamber 3, outside of the vacuum chamber 3.

In the present embodiment, an inert-gas supplying pipe 35 is connected to the inert-gas supplying portion 36 and is opened at its one end near the target 22. Further, a reactive-gas supplying pipe 33 is connected to the reactive-gas supplying portion 37 and is opened at its one end near the substrate 8. The vacuum pump 34 is communicated with the inside of the chamber 3 through an exhaust pipe 34a.

The back surface of the backing plate 43 is connected to the negative electrode of a direct-current power supply 6 and the inner wall surface of the vacuum chamber 3 is connected to the ground potential.

In the present embodiment, similarly to the aforementioned embodiments, an anode 90 is provided near the target 22. The anode 90 is secured to the shield cover 72. In the present embodiment, the anode 90 is constituted by a member having a narrow width, a small thickness and a large length and having two bent portions. The anode 90 is made of an electrically-conductive member having a high melting point such as tungsten.

In the present embodiment, as illustrated in FIG. 8, the tip end portion of the anode 90 at its one end is placed in the region where plasma is retained, namely the region where magnetic fields are generated from the magnets 51a and 51b, near the target 22, while the other end portion of the anode 90 is secured to the shield cover 72. Further, the other end portion of the anode 90 is connected to the ground potential.

In the fifth embodiment, similarly, the tip end portion of the anode 90 is placed in the region where plasma is retained, near the target 22. Therefore, the tip end portion of the anode 90 is heated to a high temperature by plasma. Even when reactive gas is supplied to the chamber, the tip end portion of the anode 90 being heated to a high temperature does not react with the reactive gas and no insulation film is formed on the tip end portion.

With the present embodiment, similarly, electrons discharged from the target can flow to the ground potential, through the tip end portion of the anode 90 being heated to a high temperature by plasma, during sputtering.

As a result, even when an insulation film is formed on the exposed surfaces of the anode 90 other than the heated portion thereof, no insulation film is formed on the heated portion, which allows electrons discharged from the target to be grounded through the heated portion of the anode any time. As a result, even when an insulation film is formed on the chamber inner wall surface during sputtering, it is possible to keep the direct-current power supply circuit at a closed state, which prevents rises of the electrical-discharge voltage within the chamber 3.

### EXAMPLES

Measurements for changes of the electric-discharge voltage during sputtering were conducted using an opposite-targets type sputtering apparatus. The measurements of voltages were conducted as follows. A sputtering apparatus in which an insulation film had been already formed on the entire inner wall surface of the chamber was prepared. Then, measurements of voltages were conducted using the sputtering apparatus in which an insulation film had been formed therein, for the case of using the anode constituted by the first member and the second member according to the aforementioned first embodiment and for the case of using a pulsed power supply as described in the prior art.

The first member was formed from a member made of tantalum having a width of 0.3 cm, a thickness of 3.0 mm and a length of 5.0 cm. The second member was formed from a member made of a stainless steel having a width of 1.0 cm, a thickness of 1.0 mm and a length of 5.0 cm. Further, silicon was used as the target, argon gas was used as the inert gas and oxygen was used as the reactive gas.

The result of measurements is illustrated in a graph of FIG. 9. The measurement of electric-discharge voltage was conducted plural times at predetermined elapsed times. The graph of FIG. 9 represents the variations of voltage measurements at the respective predetermined elapsed times by vertical lines connecting a maximum value and a minimum value and represents the averages of measured values by round marks.

In the present example, a comparison was made among the electrical-discharge voltage generated by using the anode according to the present invention, the electrical-discharge voltage generated by using the pulsed power supply and the electrical-discharge voltage generated by using the sputtering apparatus in which an insulation film had been formed on the chamber inner wall surface but no insulation film had been formed on the shield cover (the shield cover had been cleaned). FIG. 9 also represents the change of the electric-discharge voltage during sputtering using the sputtering apparatus in which an insulation film had been formed on the chamber inner wall surface but no insulation film had been formed on the shield cover.

As can be seen from the graph, during the sputtering using the sputtering apparatus in which no insulation film had been formed on the shield cover, the voltage rose as an insulation film was gradually formed on the shield cover. However, when the anode according to the present invention was employed, the electric-discharge voltage within the chamber did not rise.

When the pulsed power supply was used, the electric-discharge voltage was raised as conventional and further the variation of the voltage was large.

### INDUSTRIAL APPLICABILITY

The sputtering apparatus according to the present invention is particularly suitable as a sputtering apparatus for forming insulation films.

### BRIEF DESCRIPTION OF DRAWINGS

FIG. 1 is an entire structural view of a sputtering apparatus according to a first embodiment of the present invention.

FIG. 2 is a partially enlarged cross-sectional view of the portion where the anode is placed in the sputtering apparatus according to the first embodiment.

FIG. 3 is a plan view of the first member of the anode of FIG. 2.

FIG. 4 is a plan view of the second member of the anode of FIG. 2.

FIG. 5 is a perspective view illustrating a state where the anode is mounted to the shield cover, according to a second embodiment of the sputtering apparatus of the present invention.

FIG. 6 is a plan view of the first member of the anode according to a third embodiment of the anode of the sputtering apparatus of the present invention.

FIG. 7 is a plan view of the second member of the anode according to a fourth embodiment of the anode of the sputtering apparatus of the present invention.

FIG. 8 is an entire structural view of a sputtering apparatus according to a fifth embodiment of the present invention.

FIG. 9 is a graph illustrating the result of measurements of electric-discharge voltages within the chamber of a sputtering apparatus.

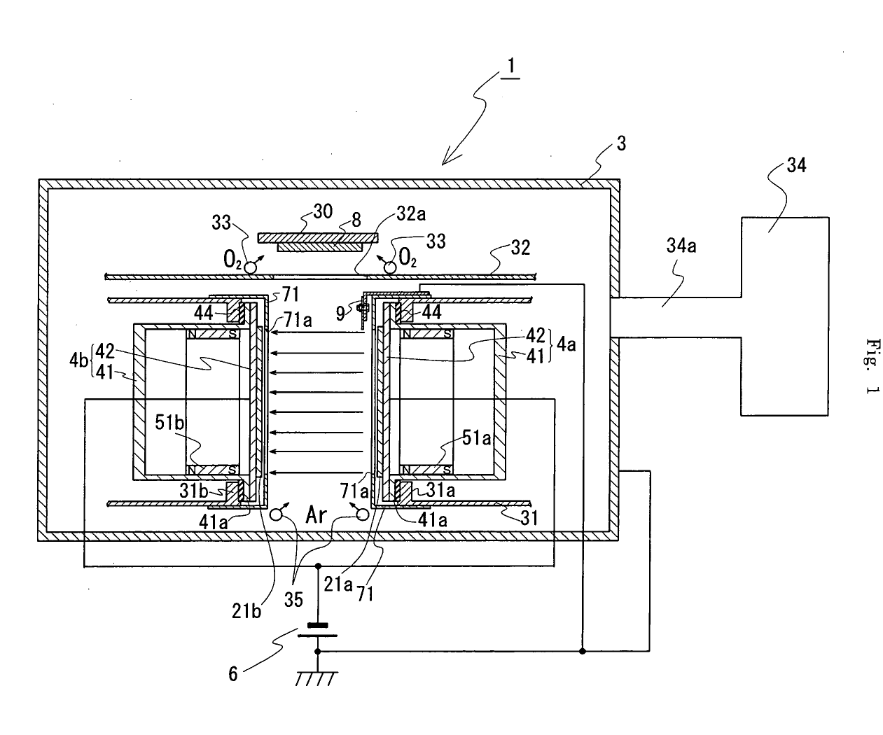

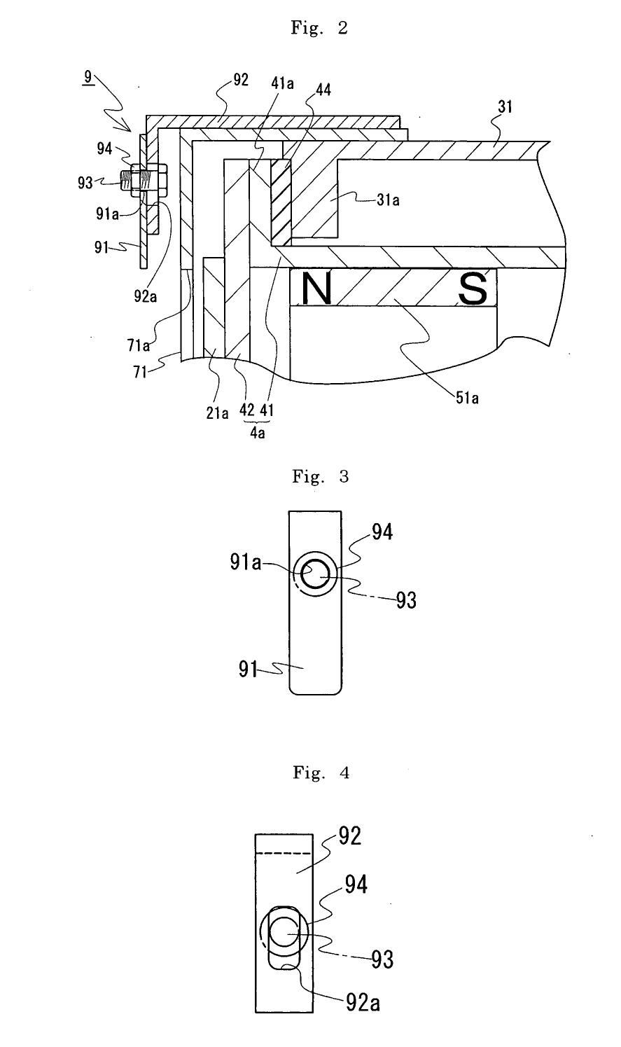

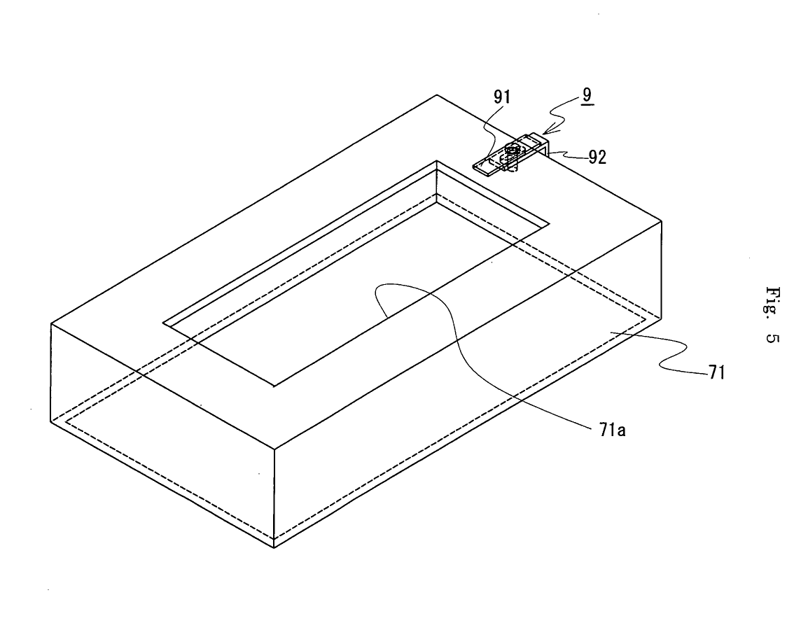

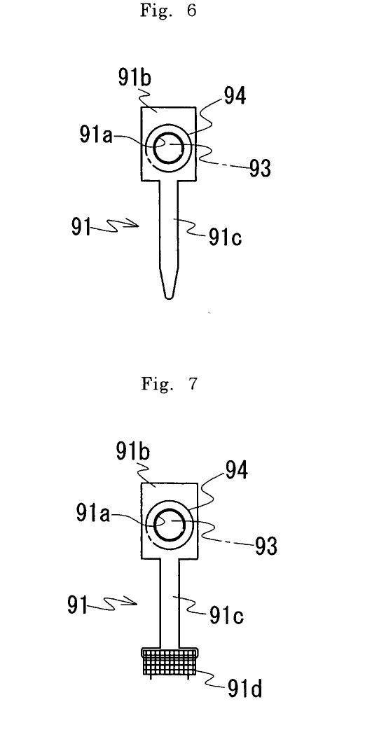

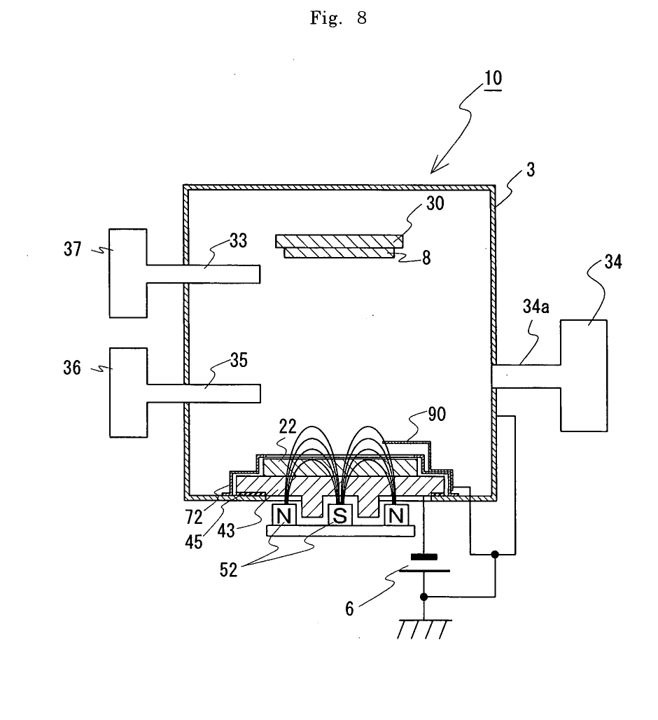

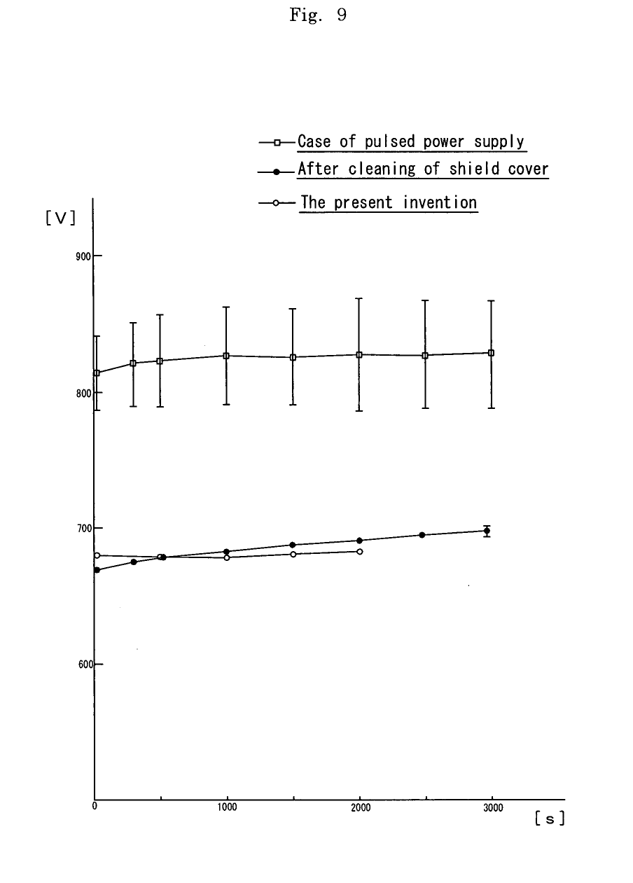

### EXPLANATIONS OF LETTERS OR NUMERALS

1, 10 sputtering apparatus
21a, 21b, 21 target
3 chamber
30 substrate holder
31 supporting cylindrical member
31a first flange portion
32 artition wall
32a opening
33 reactive-gas supplying pipe
34 vacuum pump
34a exhaust pipe
35 inert-gas supplying pipe
36 inert-gas supplying portion
37 reactive-gas supplying portion
4a, 4b target holder
41 magnet housing portion
41a second flange portion
42, 43 backing plate
44, 45 insulation member
51a, 51b, 52 magnet
6 direct-current power supply
71, 72 shield cover
71a opening portion
8 substrate
9, 90 anode
91 first member
91a bolt inserting hole
91b fixed portion
91c narrow-width portion
91d mesh-shaped member
92 second member
92a long hole
93 bolt
94 nut

1. A sputtering apparatus which comprises a target holder that constitutes a cathode with a target being mounted thereon, a substrate holder that holds a substrate away from the target, a chamber in which the holders are disposed, and a magnet that generates a magnetic field around a surface of the target, and which applies a voltage from a direct-current power supply to the target holder, generates plasma near the target surface so as to be retained by the magnetic field generated by the magnet, thereby depositing a thin film on the substrate, the apparatus comprising:
an anode made of an electrically-conductive material that is not molten by heating from the retained plasma,
wherein the anode is connected to a ground potential, and at least a portion of the anode is disposed in or in vicinity of a region where the plasma is retained.

2. The sputtering apparatus according to claim 1, wherein the anode is made of an electrically-conductive material having a melting point of 1000° C. or higher.

3. The sputtering apparatus according to claim 1, wherein the anode is constituted from an elongate member with a narrow width, and one end of the anode is positioned near the target and the other end is connected to the ground potential.

4. The sputtering apparatus according to claim 1, wherein the anode includes a position adjustment mechanism for adjusting a position of the anode with respect to the region where plasma is retained.

5. The sputtering apparatus according to claim 4, wherein
the anode includes:
a first member having an elongate plate shape with a narrow width, one end of which is positioned near the target; and
a second member having a plate shape, to which the other end of the first member is joined with a joining position adjustable, and a part of which is connected to the ground potential, wherein
the first member has a bolt inserting hole for inserting a bolt therethrough at the joining position with the second member, and the second member has a long hole for inserting the bolt therethrough at the joining position with the first member, thereby constituting the position adjustment mechanism.

6. The sputtering apparatus according to claim 5, wherein
the first member includes:
a fixed portion having the bolt inserting hole for joining the first member to the second member by inserting a bolt therethrough; and
a narrow-width portion having a smaller width than that of the fixed portion, wherein
the fixed portion and the narrow-width portion are continuously formed, and the narrow-width portion has a tapered tip end portion.

7. The sputtering apparatus according to claim 5, wherein
the first member includes:
a fixed portion having the bolt inserting hole for joining the first member to the second member by inserting a bolt therethrough; and
a narrow-width portion having a smaller width than that of the fixed portion, wherein
the fixed portion and the narrow-width portion are continuously formed, and the narrow-width portion is provided at its tip end portion, in an electrically conductive manner, with a mesh-shaped member made of an electrically-conductive material.

8. The sputtering apparatus according to one of claims 1 to 7, wherein the sputtering apparatus is an opposite-target type sputtering apparatus.

9. The sputtering apparatus according to one of claims 1 to 7, wherein the sputtering apparatus is a magnetron sputtering apparatus.
